(19) United States
(12) Patent Application Publication
(10) Pub. No.: US 2025/0176358 A1
(43) Pub. Date: May 29, 2025

(54) THIN FILM TRANSISTOR AND DISPLAY DEVICE COMPRISING SAME

(71) Applicant: LG DISPLAY CO., LTD., Seoul (KR)

(72) Inventor: Jangdae KIM, Paju-si (KR)

(73) Assignee: LG DISPLAY CO., LTD., Seoul (KR)

(21) Appl. No.: 18/794,565

(22) Filed: Aug. 5, 2024

(30) Foreign Application Priority Data
Nov. 28, 2023 (KR) 10-2023-0168022

(51) Int. Cl. H10K 59/121; H10K 59/126; H10K 77/10; H10K 102/00

(52) U.S. Cl. CPC H10K 59/1213; H10K 59/126; H10K 77/111; H10K 2102/311

(57) ABSTRACT

A display device including a substrate; a semiconductor layer including a first semiconductor layer formed on the substrate and a second semiconductor layer formed on the first semiconductor layer, wherein the second semiconductor layer contacts side surfaces and an upper surface of the first semiconductor layer and has a first end protruding away from a first side surface of the first semiconductor layer and a second end protruding away from a second side surface of the first semiconductor layer; a gate electrode overlapping the first semiconductor layer; and a first electrode connected to the first end of the second semiconductor layer protruding away from the first side surface of the first semiconductor layer and a second electrode connected to the second end of the second semiconductor layer protruding away from the second side surface of the first semiconductor layer.

### CROSS REFERENCE TO RELATED APPLICATION

The present application claims priority to Korean Patent Application No. 10-2023-0168022, filed Nov. 28, 2023, the entire contents of which is incorporated herein for all purposes by this reference.

### BACKGROUND OF THE INVENTION

### Field of the Invention

The present invention relates to a thin film transistor, and a display device including the same, and more specifically, to a high mobility thin film transistor that is robust to changes in length and width of a channel, and a display device including the same.

### Description of the Related Art

As the information society develops, various demands for display devices for displaying images are increasing, and various types of display devices such as liquid crystal display (LCD) devices and organic light emitting diode (OLED) display devices are utilized. A display device includes a plurality of pixels and a plurality of switching elements for driving and controlling the pixels. Further, the switching elements include thin film transistors, and the thin film transistors are widely applied to both the pixels and integrated circuits. Recently, various research and development have been conducted to improve the performance and reliability of the thin film transistors.

### SUMMARY OF THE INVENTION

Accordingly, one aspect of the present specification is to provide a thin film transistor and corresponding display device solving a problem that a length of an effective channel is decreased when a high-mobility thin film transistor is converted into a conductor.

Another aspect of the present specification is to provide a thin film transistor and corresponding display device in which a degradation in characteristics of the thin film transistor occurring when a gate voltage is applied to continuously turn on the thin film transistor can be minimized.

Yet another aspect of the present specification is to provide a thin film transistor and corresponding display device that minimizes a phenomenon that a threshold voltage of the thin film transistor is negative-shifted by hydrogen ions introduced from insulating layers disposed above and under a semiconductor layer by allowing a low mobility semiconductor layer to cover a whole surface of a high mobility semiconductor layer.

To achieve these and other advantages and in accordance with the purpose of the present specification, as embodied and broadly described herein, the present specification provides in one aspect a display device including a substrate, a semiconductor layer including a first semiconductor layer formed on the substrate and a second semiconductor layer formed on the first semiconductor layer and in contact with side surfaces and an upper surface of the first semiconductor layer, a gate electrode formed on the semiconductor layer and overlapping the first semiconductor layer, and a first electrode formed on the gate electrode and connected to one end of the second semiconductor layer protruding from the first semiconductor layer and a second electrode formed on the gate electrode and connected to the other end of the second semiconductor layer protruding from the first semiconductor layer.

In another aspect, the present specification provides a thin film transistor including a semiconductor layer including a first semiconductor layer and a second semiconductor layer formed on the first semiconductor layer and fully covering the first semiconductor layer, a gate electrode formed on the semiconductor layer and overlapping the first semiconductor layer, and a first electrode formed on the gate electrode and connected to one end of the second semiconductor layer protruding from the first semiconductor layer and a second electrode formed on the gate electrode and connected to the other end of the second semiconductor layer protruding from the first semiconductor layer.

In the display device according to the embodiments, by including the stacking structure in which the low mobility semiconductor layer covers the upper and side surfaces of the high mobility semiconductor layer, it is possible to minimize the degradation in characteristics of the thin film transistor due to the bias voltage of the gate electrode of the thin film transistor. In addition, by forming the length of the high mobility semiconductor layer to be smaller than the length of the gate electrode and allowing the low mobility semiconductor layer to cover the upper and side surfaces of the high mobility semiconductor layer, it is possible to minimize the reduction in length of the effective channel of the high mobility semiconductor layer.

Further, in the display device according to the embodiments, by allowing the low mobility semiconductor to cover the whole surface of the high mobility semiconductor layer, it is possible to minimize the degradation in characteristics of the thin film transistor due to the bias voltage of the dual gate electrode of the thin film transistor even in the structure of the dual gate electrode. In addition, in the display device according to the embodiments, by allowing the low mobility semiconductor layer to cover the whole surface of the high mobility semiconductor layer, it is possible to prevent the phenomenon that the threshold voltage of the thin film transistor is negative-shifted by hydrogen ions introduced from the insulating layers disposed above and under the semiconductor layer.

Further scope of applicability of the present invention will become apparent from the detailed description given hereinafter. However, the detailed description and specific examples, while indicating preferred embodiments of the invention, are given by illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings, which are given by illustration only, and thus are not limitative of the present invention, and wherein:

FIG. 1 is a block diagram schematically showing a display device according to one embodiment.

FIG. 2 is a view showing a pixel circuit in the display device according to one embodiment.

FIG. 3 is a plan view of a thin film transistor according to a first embodiment.

FIG. 4 is a cross-sectional view along line A-A′ in FIG. 3.

FIGS. 5 and 6 are schematic diagrams showing a degradation in characteristics of the thin film transistor due to a bias voltage of a gate electrode of the thin film transistor according to the first embodiment.

FIG. 7 is a cross-sectional view of a thin film transistor according to a second embodiment.

FIGS. 8 and 9 are schematic diagrams showing that a length of an effective channel of a high mobility semiconductor layer of the thin film transistor according to the second embodiment is decreased.

FIG. 10 is a plan view of a thin film transistor according to a third embodiment.

FIG. 11 is a cross-sectional view along line B-B′ in FIG. 10.

FIG. 12 is a cross-sectional view of a thin film transistor according to a fourth embodiment.

FIG. 13 is a plan view of a thin film transistor according to a fifth embodiment.

### DETAILED DESCRIPTION OF THE INVENTION

Hereinafter, embodiments will be described with reference to the accompanying drawings. The same reference numerals indicate the same components. In addition, in the drawings, thicknesses, proportions, and dimensions of components can be exaggerated for effective description of technical contents. Scales of components illustrated in the drawings differ from the actual scale for convenience of description, and thus are not limited to the scales illustrated in the drawings.

In the specification, when a first component (or an area, a layer, a portion, or the like) is described as “on,” “connected,” or “coupled to” a second component, it means that the first component can be directly connected/coupled to the second component or a third component can be disposed therebetween. The term “and/or” includes all one or more combinations that can be defined by the associated configurations. Terms such as first and second can be used to describe various components, but the components are not limited by the terms. The terms are used only for the purpose of distinguishing one component from another. For example, a first component can be referred to as a second component, and similarly, the second component can also be referred to as the first component without departing from the scopes of the embodiments. The singular expression includes the plural expression unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions can be positioned between two portions. The spatially relative terms “below or beneath,” “lower,” “above,” “upper,” and the like can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element can be disposed “above” another element. Therefore, the exemplary term “below” can include both downward and upward directions.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance. Features of various embodiments of the present specification can be coupled or combined partially or entirely, and various technological interworking and driving are possible, and the embodiments can be implemented independently of each other or implemented together in an associated relationship.

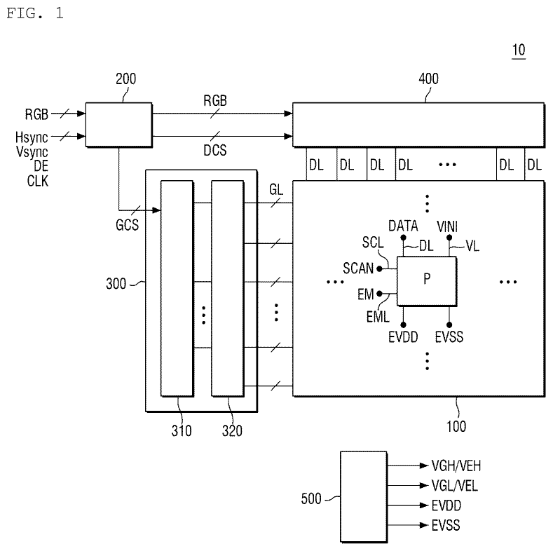

Hereinafter, a display device of the present specification will be described through the accompanying drawings and embodiments as follows. In particular, FIG. 1 is a block diagram schematically showing a display device 10 according to one embodiment. Referring to FIG. 1, the display device 10 includes a display panel 100 including a plurality of pixels P, a controller 200, a gate driving unit 300 for supplying gate signals to each pixel P, a data driving unit 400 for supplying data signals to each pixel P, and a power supply unit 500 for supplying power required for driving each pixel P.

In addition, the display panel 100 includes a display area in which the pixels P are located and a non-display area surrounding the display area and in which the gate driving unit 300 and the data driving unit 400 are disposed. In the display panel 100 shown in FIG. 1, a plurality of scan lines SCL and a plurality of data lines DL cross each other, and each pixel P is connected to the scan line SCL and the data line DL. Specifically, one pixel P receives the gate signals from the gate driving unit 300 through the gate line SCL, receives a data voltage DATA from the data driving unit 400 through the data line DL, and receives a high potential driving voltage EVDD and a low potential driving voltage EVSS from the power supply unit 500.

Here, the scan line SCL supplies the scan signal SCAN and an emission control signal EM, and the data line DL supplies the data voltage DATA. In addition, according to various embodiments, the scan line SCL can include a plurality of scan lines SCL through which the scan signal SCAN is supplied and an emission control signal line EML through which the emission control signal EM is supplied. Also, the plurality of pixels P can further include an initialization power line VIL to receive an initialization voltages VINI.

In addition, each of the pixels P includes a light emitting element OLED and a pixel circuit for controlling the driving of the light emitting element OLED. Here, the light emitting element OLED includes an anode, a cathode, and a light emitting layer between the anode and the cathode.

Further, the pixel circuit includes a plurality of switching elements, a driving element, and a capacitor. Here, the switching element and the driving element can be formed of thin film transistors. In the pixel circuit, the driving element adjusts the amount of light emitted from the light emitting element OLED by controlling the amount of current supplied to the light emitting element OLED according to the data voltage. In addition, the plurality of switching elements operate the pixel circuits after receiving the scan signals SCAN supplied through the plurality of scan lines SCL and the emission control signal EM supplied through the emission control line EML.

Further, the display panel 100 can be implemented as a non-transmissive display panel or a transmissive display panel. In particular, the transmissive display panel can be applied to a transparent display apparatus in which images are displayed on a screen and a real object in the background is visible. The display panel 100 can also be manufactured as a flexible display panel. That is, the flexible display panel can be implemented as an organic light emitting diode (OLED) panel using a plastic substrate. Also, each of the pixels P can be divided into a red pixel, a green pixel, and a blue pixel to implement colors, and can further include a white pixel. Each of the pixels P includes the pixel circuit.

In addition, touch sensors can be disposed on the display panel 100 and thus touch input can be sensed using separate touch sensors or sensed through the pixels P. In more detail, the touch sensors are on-cell type or add-on type touch sensors and can be implemented as in-cell type touch sensors disposed on the screen of the display panel or embedded into the display panel 100.

Further, the controller 200 processes image data RGB input from the outside according to the size and resolution of the display panel 100 and supplies the processed image data RGB to the data driving unit 400. The controller 200 also generates a gate control signal GCS and a data control signal DCS using synchronization signals, for example, a dot clock signal CLK, a data enable signal DE, a horizontal synchronization signal Hsync, and a vertical synchronization signal Vsync, input from the outside. The controller 200 further controls the gate driving unit 300 and the data driving unit 400 by supplying the generated gate control signal GCS and data control signal DCS to the gate driving unit 300 and the data driving unit 400, respectively. In addition, controller 200 can be configured by being coupled to various processors, for example, a microprocessor, a mobile processor, an application processor, and the like, depending on a device to be mounted.

Also, a host system can be any one of a television (TV) system, a set-top box, a navigation system, a personal computer (PC), a home theater system, a mobile device, a wearable device, and a vehicle system. Further, the controller 200 can control operation timings of a display panel driver at a frame frequency of an input frame frequency Xi Hz by multiplying the input frame frequency by i times (i is a positive integer greater than zero). In particular, the input frame frequency is 60 Hz in a national television standards committee (NTSC) type and 50 Hz in a phase-alternating line (PAL) type.

In addition, the controller 200 generates signals so that the pixel P can be driven at various refresh rates. In other words, the controller 200 generates signals associated with driving so that the pixel P is driven in a variable refresh rate (VRR) mode or to be switched between a first refresh rate and a second refresh rate. For example, the controller 200 can drive the pixel P at various refresh rates by simply changing rates of clock signals, generating synchronization signals to generate a horizontal blank or a vertical blank, or driving the gate driving unit 300 in a mask manner.

Also, the controller 200 generates the gate control signal GCS for controlling an operation timing of the gate driving unit 300 and the data control signal DSC for controlling an operation timing of the data driving unit 400 based on timing signals Vsync, Hsync, and DE received from the host system. The controller 200 also synchronizes the gate driving unit 300 and the data driving unit 400 by controlling operation timings of the display panel driver.

In addition, a voltage level of the gate control signal GCS output from the controller 200 can be converted into gate-on voltages VGL and VEL and gate-off voltages VGH and VEH through a level shifter and supplied to the gate driving unit 300. The level shifter converts a low level voltage of the gate control signal GCS into the gate low voltage VGL and converts a high level voltage of the gate control signal GCS into the gate high voltage VGH. The gate control signal GCS includes a start pulse and a shift clock.

Further, the gate driving unit 300 supplies the scan signal SCAN to the scan line SCL according to the gate control signal GCS supplied from the controller 200. The gate driving unit 300 can also be disposed at one side or both sides of the display panel 100 by a gate in panel (GIP) method. In addition, the gate driving unit 300 sequentially outputs the gate signals to the plurality of scan lines SCL under the control of the controller 200, and can shift the gate signals using the shift register to sequentially supply the signals to the scan lines SCL.

In addition, the gate signal can include the scan signal SCAN and the emission control signal EM in an OLED display device. In more detail, the scan signal SCAN includes a scan pulse that swings between the gate-on voltage VGL and the gate-off voltage VGH, and the emission control signal EM can include an emission control signal pulse that swings between the gate-on voltage VEL and the gate-off voltage VEH.

Further, the scan pulse is synchronized with the data voltage DATA to select pixels P in a line in which data is written, and the emission control signal EM defines emission times of the pixels P. The gate driving unit 300 can also include an emission control signal driver 310 and at least one scan driver 320.

In addition, the emission control signal driver 310 outputs the emission control signal pulse in response to the start pulse and the shift clock from the controller 200 and sequentially shifts the emission control signal pulse according to the shift clock. The at least one scan driver 320 also outputs the scan pulse in response to the start pulse and the shift clock from the controller 200 and shifts the scan pulse according to a shift clock timing. Further, the data driving unit 400 converts the image data RGB into the data voltage DATA according to the data control signal DCS supplied from the controller 200 and supplies the converted data voltage DATA to the pixel P through the data line DL.

FIG. 1 illustrates the data driving unit 400 disposed at one side of the display panel 100 as a single data driving unit, but the number and arrangement positions of data driving units 400 are not limited thereto. In other words, the data driving unit 400 can be formed of a plurality of integrated circuits (IC) and disposed separately as a plurality of data driving units at one side of the display panel 100.

In addition, the power supply unit 500 generates direct current (DC) power required for driving a pixel array and the display panel driving unit of the display panel 100 using a DC-DC converter. In more detail, the DC-DC converter can include a charge pump, a regulator, a buck converter, a boost converter, and the like. Also, the power supply unit 500 can receive a DC input voltage applied from the host system (not shown) and generate DC voltages such as the gate-on voltages VGL and VEL, the gate-off voltages VGH and VEH, the high potential driving voltage EVDD, and the low potential driving voltage EVSS. The gate-on voltages VGL and VEL and the gate-off voltages VGH and VEH are also supplied to the level shifter and the gate driving unit 300, and the high potential driving voltage EVDD and the low potential driving voltage EVSS are commonly supplied to the pixels P.

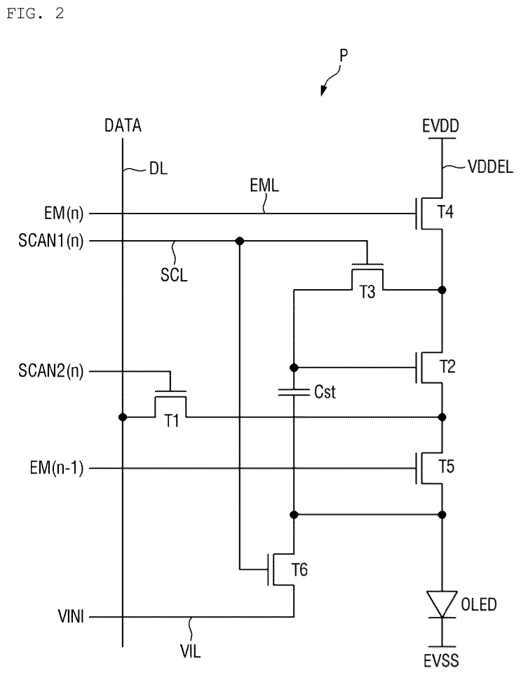

Next, FIG. 2 is a view showing a pixel circuit in the display device according to one embodiment. Referring to FIGS. 1 and 2, each pixel P includes first to sixth thin film transistors T1 to T6, a capacitor CST, and the light emitting element OLED connected to the pixel circuit.

Further, the pixel circuit drives the light emitting element OLED by controlling a driving current flowing in the light emitting element OLED. The pixel circuit can include the first to sixth transistors T1 to T6 and the capacitor CST. Each of the thin film transistors T1 to T6 can include a first electrode, a second electrode, and a gate electrode. One of the first electrode and the second electrode can be a source electrode, and the other can be a drain electrode.

Each of the thin film transistors T1 to T6 can be a p-type thin film transistor or an n-type thin film transistor. In the embodiment of FIG. 2, all thin film transistors T1 to T6 are shown as being n-type thin film transistors. However, the present invention is not limited thereto, and according to the embodiment, some of the thin film transistors T1 to T6 can be formed as p-type thin film transistors. In addition, the n-type thin film transistor can be an oxide thin film transistor, and the p-type thin film transistor can be a polycrystalline silicon thin film transistor.

Hereinafter, all thin film transistors T1 to T6 are described as n-type thin film transistors. Therefore, the thin film transistors T1 to T6 are turned on by receiving a high voltage.

According to one example, the second transistor T2 forming the pixel circuit can serve as a driving transistor, the third transistor T3 can serve as a compensation transistor, the first thin film transistor T1 can serve as a data supply transistor, the fourth and fifth transistors T4 and T5 can serve as emission control transistors, and the sixth transistor T6 can serve as an initialization transistor. The second thin film transistor T2 can be a driving element, and the first thin film transistor T1, the third thin film transistor T3 to the sixth thin film transistor T6 can be switching elements.

In addition, the light emitting element OLED includes an anode and a cathode. In particular, the anode of the light emitting element OLED can be connected to a second electrode of the fifth transistor T5, and the cathode thereof can be connected to the low potential driving voltage EVSS. Further, the second thin film transistor T2 can include a first electrode connected to a second electrode of the fourth transistor T4, a second electrode connected to a first electrode of the fifth transistor T5, and a gate electrode connected to a second electrode of the third transistor T3. Also, the second thin film transistor T2 can provide a driving current to the light emitting element OLED based on a data voltage stored in the capacitor CST.

In addition, the third thin film transistor T3 can include a first electrode connected to the second electrode of the fourth transistor T4, a second electrode connected to a gate electrode of the second thin film transistor T2, and a gate electrode for receiving a first scan signal SCAN1(n). Also, the third thin film transistor T3 can be turned on in response to the first scan signal SCAN1(n) and diode-connected between the first electrode and the second electrode to sample a threshold voltage (Vth) of the second thin film transistor T2. The third thin film transistor T3 can be the compensation transistor.

Further, capacitor CST can be connected or formed between the second electrode of the third thin film transistor T3 (or the gate electrode of the second thin film transistor T2) and the anode of the light emitting element OLED. As shown in FIG. 2, the first thin film transistor T1 can include a first electrode connected to the data line DL (or for receiving the data voltage DATA), a second electrode connected to the second electrode of the second thin film transistor T2 (or a first electrode of the fifth thin film transistor T5), and a gate electrode for receiving a second scan signal SCAN2(n). The first thin film transistor T1 can thus be turned on in response to the second scan signal SCAN2(n) and can transmit the data voltage DATA to the second electrode of the second thin film transistor T2 (or the first electrode of the fifth thin film transistor T5). Also, the first thin film transistor T1 can be a data supply transistor.

As shown in FIG. 2, the fourth thin film transistor T4 and the fifth thin film transistor T5 (or the first and second emission control transistors) can be connected to the high potential voltage line VDDEL, connected between the high potential driving voltage EVDD and the light emitting element OLED, and can form a current movement path through which the driving current generated by the second thin film transistor T2 moves. Further, the fourth thin film transistor T4 can include a first electrode for receiving the high potential driving voltage EVDD, a second electrode connected to the first electrode of the second thin film transistor T2 (or the first electrode of the third thin film transistor T3), and a gate electrode for receiving an emission control signal EM(n).

In addition, the fifth thin film transistor T5 can include a first electrode connected to the second electrode of the second thin film transistor T2 (or the second electrode of the first thin film transistor T1), a second electrode connected to a second electrode of the sixth thin film transistor T6 (or the anode electrode of the light emitting element OLED), and a gate electrode for receiving an emission control signal EM(n-1). As shown in FIG. 2, the fourth and fifth thin film transistors T4 and T5 can be turned on in response to the emission control signals EM(n) and EM(n-1), respectively, and in this instance, the driving current can be provided to the light emitting element OLED, and the light emitting element OLED can emit light with brightness corresponding to the driving current. In FIG. 2, the fourth and fifth thin film transistors T4 and T5 are shown as being turned on in response to the emission control signals EM(n) and EM(n-1), respectively, but are not limited thereto, and the fourth and fifth thin film transistors T4 and T5 can be turned on in response to the same emission control signal EM(n).

In addition, the sixth thin film transistor T6 can include a first electrode for receiving an initialization voltage VINI, a second electrode connected to the anode of the light emitting element OLED, and a gate electrode for receiving the first scan signal SCAN(n). Thus, the sixth thin film transistor T6 can be turned on in response to the first scan signal SCAN(n) before the light emitting element OLED emits light (or after the light emitting element OLED emits light) and can initialize the anode (or a pixel electrode) of the light emitting element OLED using the initialization voltage VINI. The light emitting element OLED can also have a parasitic capacitor formed between the anode and the cathode. In addition, while the light emitting element OLED emits light, the parasitic capacitor can be charged so that the anode of the light emitting element OLED can have a specific voltage. Therefore, the amount of charge accumulated in the light emitting element OLED can be initialized by applying the initialization voltage VINI to the anode of the light emitting element OLED through the sixth thin film transistor T6.

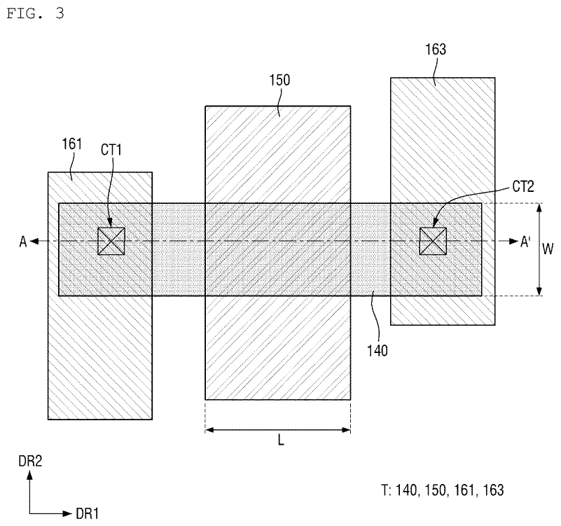

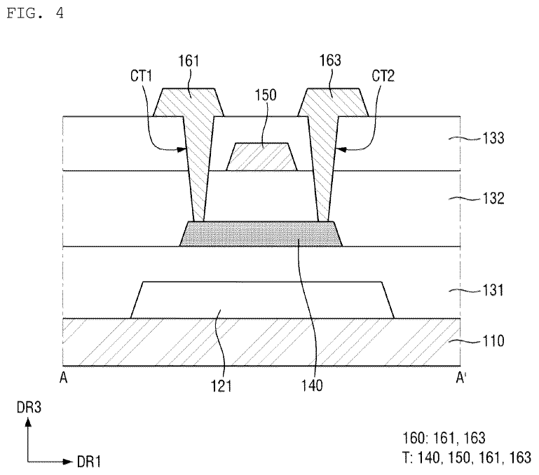

Hereinafter, thin film transistors according to the embodiments will be described. In particular, FIG. 3 is a plan view of a thin film transistor according to a first embodiment, and FIG. 4 is a cross-sectional view along line A-A′ in FIG. 3. Referring to FIGS. 3 and 4, the display device includes a substrate 110, a lower metal layer 121 formed on the substrate 110, a buffer layer 131 formed on the lower metal layer 121, a semiconductor layer 140 formed on the buffer layer 131, a gate insulating layer 132 formed on the semiconductor layer 140, a gate electrode 150 formed on the gate insulating layer 132, an interlayer insulating layer 133 formed on the gate electrode 150, and a source drain conductive layer 160 formed on the interlayer insulating layer 133 and including a first electrode 161 and a second electrode 163.

In addition, the substrate 110 can support each layer disposed thereon. In more detail, the substrate 110 can be made of an insulating material such as a polymer resin. Examples of the polymer material include polyethersulphone (PES), polyacrylate (PA), polyarylate (PAR), polyetherimide (PEI), polyethylene napthalate (PEN), polyethylene terepthalate (PET), polyphenylene sulfide (PPS), polyallylate, polyimide (PI), polycarbonate (PC), cellulose triacetate (CAT), cellulose acetate propionate (CAP), or combinations thereof. The substrate 110 can be a flexible substrate capable of bending, folding, rolling, and the like. That is, the substrate 110 may be referred as a flexible substrate. An example of a material forming the flexible substrate can be polyimide (PI), but is not limited thereto. Further, the substrate 110 can be a rigid substrate made of glass, quartz, or the like. The substrate 110 can also include multi layers. For example, the display device can be a foldable display device.

As shown in FIG. 4, the lower metal layer 121 can be disposed on the substrate 110. The lower metal layer 121 can also include a metal material. For example, the lower metal layer 121 can include one or more selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu). The lower metal layer 121 can include a light blocking layer that overlaps at least one of the thin film transistors of the pixel P or a lower gate electrode that overlaps at least one of the thin film transistors of the pixel P, which have been described above in FIG. 2, but is not limited thereto.

Further, the buffer layer 131 can be disposed on the lower metal layer 121. In particular, the buffer layer 131 can include an inorganic material. For example, the inorganic material can include silicon oxide (SiOx), silicon nitride (SiNx), or silicon oxynitride (SiOxNy), but is not limited thereto. The buffer layer 131 can thus prevent the diffusion of impurity ions and prevent the permeation of moisture or outside air. In addition, the buffer layer 131 can include a plurality of layers. In other words, the buffer layer 131 can be formed of layers of silicon nitride (SiNx) and silicon oxide (SiOx) alternately stacked at least once.

Further, the semiconductor layer 140 can be disposed on the buffer layer 131 and can include oxide. For example, the semiconductor layer 140 can be an oxide semiconductor layer. However, the present invention is not limited thereto, and the semiconductor layer 140 can include polycrystalline silicon. Hereinafter, for convenience of description, the semiconductor layer 140 shown in FIGS. 3 and 4 is described as an oxide semiconductor layer.

In addition, the semiconductor layer 140 can include a channel area, a first area, and a second area. In more detail, the channel area can include the first area and the second area. Also, the electrical conductivity of the first and second areas can be higher than that of the channel area of the semiconductor layer 140. Therefore, the first and second areas of the semiconductor layer 140 can each be converted into a conductor through, for example, an implant process.

Further, the channel area of the semiconductor layer 140 can overlap the gate electrode 150 formed thereabove. Also, the metal layer 121 formed under the semiconductor layer 140 can overlap the semiconductor layer 140, and a length of the lower metal layer 121 can be larger than a length of the semiconductor layer 140.

In addition, the oxide semiconductor can include, for example, a binary compound (ABx), a ternary compound (ABxCy), or a quaternary compound (ABxCyDz) containing indium, zinc, gallium, tin, titanium, aluminum, hafnium (Hf), zirconium (Zr), magnesium (Mg), or the like. The semiconductor layer 140 according to the first embodiment can be a high mobility semiconductor layer. In the present specification, the high mobility semiconductor layer can indicate a semiconductor layer of which an electron mobility is 20 cm2/VS or more. For example, the semiconductor layer 140 can include an IZO (oxide containing indium and titanium) in which the content of indium (In) is about 5 times higher than the content of gallium (Ga) and gallium (Ga) is omitted from IGZO (oxide containing indium, gallium, tin, and titanium), or IZSn in which gallium is omitted from IGZO and which contains a metal with high electrical conductivity, such as tin (Sn), but is not limited thereto.

On the other hand, the low mobility semiconductor layer described below can indicate a semiconductor layer with an electron mobility of 10 cm2/VS to 15 cm2/VS. For example, the low mobility semiconductor layer can be made of ITZO (oxide containing indium, tin, and titanium) in which the contents of indium (In), tin (Tin), and zinc (Zn) are 1:1:1, but is not limited thereto.

Referring back to FIGS. 3 and 4, the gate insulating layer 132 can be disposed on the semiconductor layer 140 and can include an inorganic material. For example, the inorganic material can include silicon oxide (SiOx), silicon nitride (SiNx), or silicon oxynitride (SiOxNy), but is not limited thereto. Also, the gate insulating layer 132 can include a plurality of layers. In other words, the gate insulating layer 132 can be formed of layers of silicon nitride (SiNx) and silicon oxide (SiOx) alternately stacked at least once. For example, the gate insulating layer 132 can serve to insulate the gate electrode 150 and the semiconductor layer 140.

In addition, the gate electrode 150 can be disposed on the gate insulating layer 132 and can overlap the channel area of the semiconductor layer 140 of a thin film transistor T. For example, the gate electrode 150 can include one or more selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu). A length of the gate electrode 150 can be smaller than a length of the semiconductor layer 140.

Further, the interlayer insulating layer 133 can be disposed on the gate electrode 150 and can include an inorganic material. For example, the inorganic material can include silicon oxide (SiOx), silicon nitride (SiNx), or silicon oxynitride (SiOxNy), but is not limited thereto. In addition, the interlayer insulating layer 133 can include a plurality of layers. In other words, the interlayer insulating layer 133 can be formed of layers of silicon nitride (SiNx) and silicon oxide (SiOx) alternately stacked at least once. For example, the interlayer insulating layer 133 can serve to insulate the gate electrode 150 and the source drain conductive layer 160 to be described below.

Further, the source drain conductive electrode 160 can be disposed on the interlayer insulating layer 133 and can include the first electrode 161 and the second electrode 163. The first electrode 161 can be electrically connected to the first area of the semiconductor layer 140 through a first contact hole CT1 passing through the interlayer insulating layer 133 and the gate insulating layer 132 in the thickness direction. In addition, the second electrode 163 can be electrically connected to the second area of the semiconductor layer 140 through a second contact hole CT2 passing through the interlayer insulating layer 133 and the gate insulating layer 132 in the thickness direction.

Also, the thin film transistor T according to the first embodiment can include the semiconductor layer 140, the gate electrode 150, the first electrode 161, and the second electrode 163. The thin film transistor T according to the first embodiment can also include one of the thin film transistors T1 to T6 shown in FIG. 2.

As shown in FIG. 3, the semiconductor layer 140 can have a length defined in a first direction DR1 and a width defined in a second direction DR2. A length L of the channel area of the semiconductor layer 140 can also be designed to be equal to a length of the gate electrode 150, and a width W of the semiconductor layer 140 can be smaller than a width of the gate electrode 150.

Further, the semiconductor layer 140 is a high mobility semiconductor layer, and the buffer layer 131 and the interlayer insulating layer 132 that are respectively disposed under and above the semiconductor layer 140 can contain hydrogen ions. The hydrogen ions of the buffer layer 131 and the interlayer insulating layer 132 can each be generated in a manufacturing process of the buffer layer 131 and the interlayer insulating layer 132 and can be contained in the buffer layer 131 and the interlayer insulating layer 132. Because the semiconductor layer 140 is a high mobility semiconductor layer, when the hydrogen ions of the buffer layer 131 and the interlayer insulating layer 132 permeate the semiconductor layer 140, the hydrogen ions can be neutralized in the semiconductor layer 140 to emit electrons. The electrons generated by neutralizing the hydrogen ions in the semiconductor layer 140 can also negatively shift the threshold voltage of the thin film transistor T including the semiconductor layer 140.

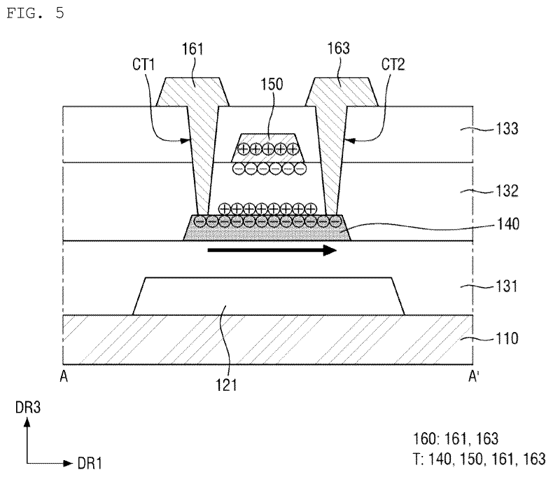

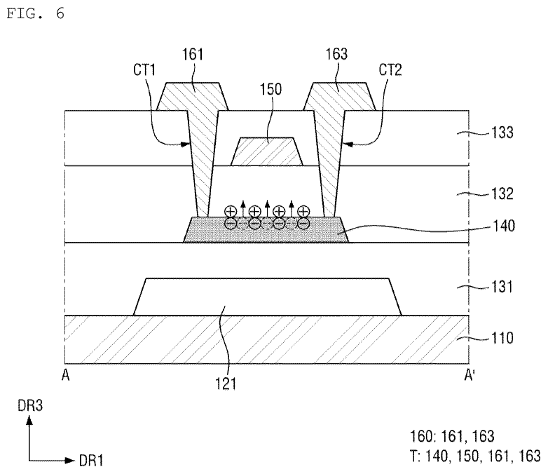

Next, FIGS. 5 and 6 are schematic diagrams showing a degradation in characteristics of the thin film transistor due to a bias voltage of a gate electrode of the thin film transistor according to the first embodiment. As shown in FIG. 5, a gate bias voltage can be applied to the gate electrode 150 to turn on the thin film transistor T. For example, a turn-on voltage can be applied to the gate electrode 150. When the thin film transistor Tis an n-type thin film transistor, the turn-on voltage can be a positive voltage. When the positive turn-on voltage is applied to the gate electrode 150, electrons are concentrated on an upper surface of the semiconductor layer 140, which is spaced apart from the gate electrode 150 with the interlayer insulating layer 132 interposed therebetween, by an attractive force. The electrons concentrated on the channel area can serve as a channel that electrically conducts the first area, channel area, and second area of the semiconductor layer 140 when the thin film transistor T is turned on by the gate electrode 150.

In addition, electrons can be concentrated at the interface between the gate electrode 150 and the interlayer insulating layer 132 by the gate electrode 150 to which the positive voltage is applied, and conversely, holes can be concentrated at the interface between the interlayer insulating layer 132 and the semiconductor layer 140. The holes concentrated at the interface between the interlayer insulating layer 132 and the semiconductor layer 140 can attract electrons inside the semiconductor layer 140 when the thin film transistor T is turned on, thereby making it easier for electrons to be concentrated on the upper surface of the semiconductor layer 140.

However, as shown in FIG. 6, when the thin film transistor T maintains a turned-on state for a long time, some of the electrons concentrated on the upper surface of the semiconductor layer 140 are moved to a lower surface of the interlayer insulating layer 132 by the attractive force with the holes concentrated at the interface between the interlayer insulating layer 132 and the semiconductor layer 140. When some of the electrons concentrated on the upper surface of the semiconductor layer 140 are moved to the lower surface of the interlayer insulating layer 132 by the attractive force with the holes concentrated at the interface between the interlayer insulating layer 132 and the semiconductor layer 140, even when the same positive voltage as before is applied to the gate electrode 150 to turn on the thin film transistor T, the number of electrons concentrated on the upper surface of the semiconductor layer 140 can be significantly reduced by the electrons moved to the lower surface of the interlayer insulating layer 132 from the upper surface of the semiconductor layer 140. Therefore, a greater gate voltage may be required to turn on the thin film transistor T as before, there causing a phenomenon that the threshold voltage (Vth) of the thin film transistor T is positive-shifted. This can result in the occurrence of deterioration and degradation of characteristics of the thin film transistor T.

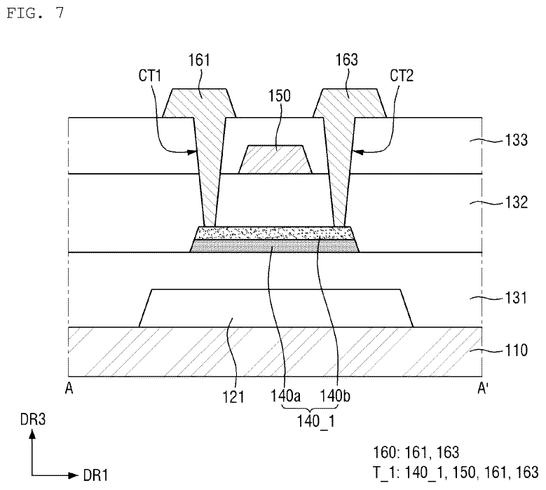

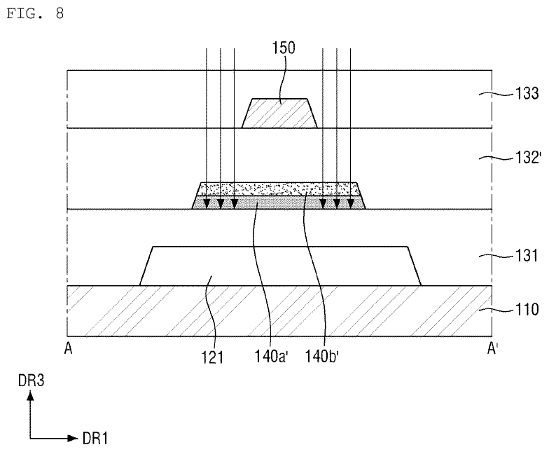

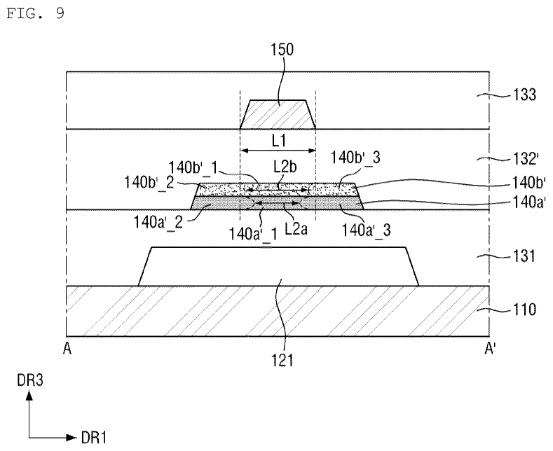

Hereinafter, embodiments in which the degradation of characteristics of the thin film transistor T to which only the high mobility semiconductor layer 140 is applied can be minimized will be described. In particular, FIG. 7 is a cross-sectional view of a thin film transistor according to a second embodiment, and FIGS. 8 and 9 are schematic diagrams showing that a length of an effective channel of a high mobility semiconductor layer of the thin film transistor according to the second embodiment is decreased.

Referring to FIGS. 7 to 9, a semiconductor layer 140_1 of a thin film transistor T_1 according to the second embodiment can be formed by stacking two or more semiconductor layers. In particular, the semiconductor layer 140_1 can include a first semiconductor layer 140a and a second semiconductor layer 140b formed on the first semiconductor layer 140a. The first semiconductor layer 140a can include the same material as the semiconductor layer 140 according to FIG. 4. Also, the first semiconductor layer 140a can be a high mobility semiconductor layer, and the second semiconductor layer 140b can be a low mobility semiconductor layer with lower electron mobility than the first semiconductor layer 140a. Further, the first semiconductor layer 140a can include oxide, and the second semiconductor layer 140b can include oxide. For example, the first semiconductor layer 140a can include IGZO, ITZO, or IGTZO, and the second semiconductor layer 140b can include IGZO, ITZO, or IGTZO. Also, the electrodes 161 and 163 can be electrically connected to the second semiconductor layer 140b through the contact holes CT1 and CT2, respectively.

According to the second embodiment, the first semiconductor layer 140a, which is the high mobility semiconductor layer, can be covered with the second semiconductor layer 140b. Because the second semiconductor layer 140b has a lower electron mobility than the first semiconductor layer 140a, when the thin film transistor T maintains the turned-on state for a long time, some of the electrons concentrated on the upper surface of the semiconductor layer 140 are moved to the lower surface of the interlayer insulating layer 132 by the attractive force with the holes concentrated at the interface between the interlayer insulating layer 132 and the semiconductor layer 140, and the number of moving electrons can be significantly reduced compared to the semiconductor layer 140 according to the first embodiment. In other words, according to the second embodiment, by further arranging the second semiconductor layer 140b, which is the low mobility semiconductor layer, between the first semiconductor layer 140a and the gate electrode 150, it is possible to prevent the phenomenon that the threshold voltage (Vth) of the thin film transistor T_1 is positive-shifted, thereby preventing the occurrence of deterioration and degradation of characteristics of the thin film transistor T_1.

Furthermore, because the second semiconductor layer 140b covers the first semiconductor layer 140a, even when the hydrogen ions of the interlayer insulating layer 132 permeate the semiconductor layer 140_1, the hydrogen ions affect the second semiconductor layer 140b and do not affect the first semiconductor layer 140a formed under the second semiconductor layer 140b. Therefore, it is possible to prevent the phenomenon that the threshold voltage of the thin film transistor T is negative-shifted.

In addition, in some embodiments, by further arranging the low mobility semiconductor layer between the first semiconductor layer 140a and the buffer layer 131, even when hydrogen ions of the buffer layer 131 permeate the semiconductor layer 140_1, the hydrogen ions affect the low mobility semiconductor layer formed under the semiconductor layer 140a and do not affect the first semiconductor layer 140a. Therefore, it is possible to prevent the phenomenon that the threshold voltage of the thin film transistor T is negative-shifted.

Next, FIGS. 8 and 9 are schematic diagrams showing a process of converting the semiconductor layer 140_1 (see FIG. 7) into a conductor during the process of forming the thin film transistor T (see FIG. 7) of the display device according to the second embodiment. As shown in FIG. 8, using the gate electrode 150 as a mask, semiconductor layers 140a′ and 140b′ are converted into conductors through the implant process. Because the gate electrode 150 serves as a mask, areas of the semiconductor layers 140a′ and 140b′ that do not overlap the gate electrode 150 are converted into conductive areas.

In FIG. 8, the portions overlapping the gate electrode 150 of the semiconductor layers 140a′ and 140b′ can be preset channel areas, one end (e.g., the first area) of the channel area can be preset as the first area, and the other end (e.g., the second area) can be preset as the second area. In other words, the lengths of the preset channel areas of the semiconductor layers 140a′ and 140b′ can be set to be the same as the length of the gate electrode 150.

However, as shown in FIG. 9, because each of the first semiconductor layer 140a′ and the second semiconductor layer 140b′ has a predetermined electron mobility, the preset channel area and an actual channel area can be formed different from each other. Hereinafter, the actual channel area will be referred to as an effective channel area. For example, lengths L2a and L2b of the effective channel areas of the first semiconductor layer 140a′ and the second semiconductor layer 140b′ can each be smaller than a preset channel area length L1.

In addition, the first semiconductor layer 140a′ can include a channel area 140a′_1, a first area 140a′_2, and a second area 140a′_3, and the second semiconductor layer 140b′ can include a channel area 140b′_1, a first area 140b′_2, and a second area 140b′_3. The channel area, first area, and second area shown in FIG. 9 can each be a preset area. However, a length of the effective channel area of each of the semiconductor layers 140a′ and 140b′ can be smaller than the length of the gate electrode 150, and lengths of an effective first area and an effective second area that are indirectly formed by the effective channel areas of the semiconductor layers 140a′ and 140b′ can also be larger than those of preset first areas 140a′_2 and 140b′_2 and second areas 140a′_3 and 140b′_3, respectively. Further, the effective first area and the effective second area that are indirectly formed by the effective channel areas of the semiconductor layers 140a′ and 140b′ can overlap the gate electrode 150.

In addition, because there is a difference in electron mobility between the first semiconductor layer 140a′ and the second semiconductor layer 140b′, the length L2a of the effective channel area of the first semiconductor layer 140a′ can be smaller than the length L2b of the effective channel area of the second semiconductor layer 140b′. In particular, in the thin film transistor T according to the second embodiment manufactured through the conducting process according to FIGS. 8 and 9, there is a problem that the length of the effective channel area of the first semiconductor layer 140a is significantly decreased, resulting in the occurrence of a short between the first area and the second area of the first semiconductor layer 140a. Therefore, because the channel area cannot be designed to have a small length, element design can be limited.

Hereinafter, embodiments solve a problem that because the length of the effective channel area is significantly decreased compared to the preset length of the channel area of the high mobility semiconductor layer during a conducting process of a thin film transistor T_1 according to the second embodiment, the element design is very limited.

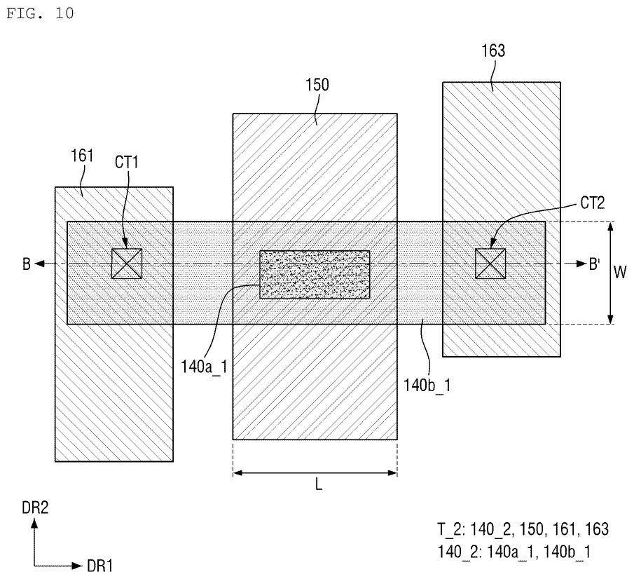

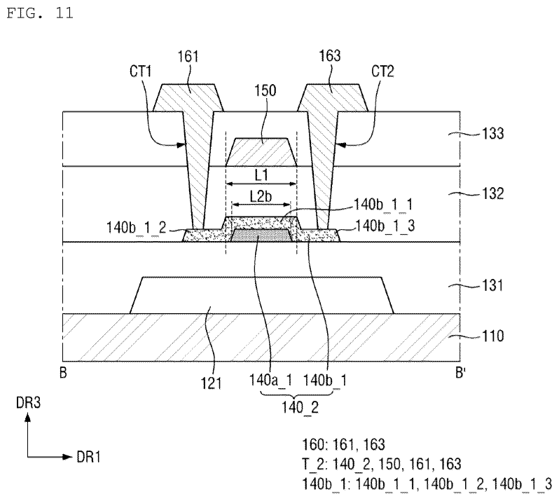

In particular, FIG. 10 is a plan view of a thin film transistor according to a third embodiment, and FIG. 11 is a cross-sectional view along line B-B′ in FIG. 10. Referring to FIGS. 10 and 11, a semiconductor layer 140_2 of a thin film transistor T_2 according to the third embodiment is formed by stacking two or more semiconductor layers and differs from the thin film transistor T_1 according to FIG. 7 in that the second semiconductor layer 140b_1 can be formed to cover the first semiconductor layer 140a_1. In this embodiment, the semiconductor layer 140_2 includes the first semiconductor layer 140a_1 disposed or formed on the substrate 110 and the second semiconductor layer 140b_1 disposed or formed on the first semiconductor layer 140a_1 and in contact with side surfaces and an upper surface of the first semiconductor layer 140a_1.

More specifically, a length of the first semiconductor layer 140a_1 can be smaller than the length of the gate electrode 150 and a length of the second semiconductor layer 140b_1, and a width of the first semiconductor layer 140a_1 can be smaller than a width of the second semiconductor layer 140b_1. In addition, the gate electrode 150 is formed on the semiconductor layer 140_2 and overlaps the first semiconductor layer 140a_1.

In addition, in this embodiment, the first electrode 161 is formed on the gate electrode 150 and connected to the semiconductor layer 140_2, and the second electrode 163 is formed on the gate electrode 150 and connected to the semiconductor layer 140_2.

As shown in FIG. 11, the preset channel area and the effective channel area of the first semiconductor layer 140a_1 can be the same as those of the second semiconductor layer 140b_1, and the first semiconductor layer 140a_1 can not include the first and second areas. On the other hand, as shown in FIG. 9, the length L2b of the effective channel area of the second semiconductor layer 140b_1 can be smaller than a preset length L of a channel area 140b_1_1. Further, the second semiconductor layer 140b_1 can include a first area 140b_1_2 at one end of the channel area 140b_1_1 and a second area 140b_1_3 at the other end thereof.

In other words, according to the thin film transistor T_2 according to the third embodiment, by designing the length of the first semiconductor layer 140a_1 to be smaller than the length of the gate electrode 150, the preset channel area of the first semiconductor layer 140a_1 with high electron mobility can be designed to be the same as the effective channel area formed by the conducting process. Therefore, in the thin film transistor manufactured through the conducting process, because the channel area cannot be designed to have a small length due to the problem that the length of the effective channel area of the first semiconductor layer 140a is significantly decreased, it is possible to increase the degree of freedom in element design by solving the problem that the element design is very limited.

In addition, as in the second embodiment of FIG. 9, by further arranging the second semiconductor layer 140b_1, which is the low mobility semiconductor layer, between the first semiconductor layer 140a_1 and the gate electrode 150, it is possible to prevent the phenomenon that the threshold voltage (Vth) of the thin film transistor T is positive-shifted, thereby preventing the occurrence of deterioration and degradation of characteristics of the thin film transistor T.

Furthermore, because the second semiconductor layer 140b_1 covers the first semiconductor layer 140a_1, even when the hydrogen ions of the interlayer insulating layer 132 permeate the semiconductor layer 140_1, the hydrogen ions affect the second semiconductor layer 140b_1 and do not affect the first semiconductor layer 140a_1 formed under the second semiconductor layer 140b. Therefore, it is possible to prevent the phenomenon that the threshold voltage of the thin film transistor T is negative-shifted.

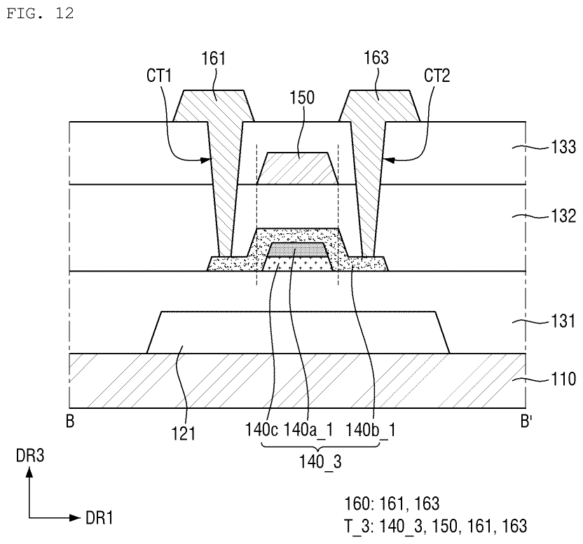

Next, FIG. 12 is a cross-sectional view of a thin film transistor according to a fourth embodiment. Referring to FIG. 12, a semiconductor layer 140_2 of a thin film transistor T_3 according to the fourth embodiment is formed by stacking three or more semiconductor layers and differs from the thin film transistor T_2 according to FIG. 11 in that a third semiconductor layer 140c can be formed between the first semiconductor layer 140a_1 and the buffer layer 131. Also, the third semiconductor layer 140c may be disposed between the first semiconductor layer 140a_1 and the substrate 110. The second semiconductor layer 140b_1 is aligned with a side of the first semiconductor layer 140a_1 or a side of the third semiconductor layer 140c.

The metal layer 121 may also be referred as a light shielding layer. The metal layer 121 is disposed between the substrate 110 and the semiconductor layer 140_2, and overlapped with the semiconductor layer 140_2. The same gate voltage is applied to the gate electrode 150 and the metal layer 121. The buffer layer 131 is located between the metal layer 121 and the semiconductor layer 140_2, and includes silicon nitride (SiNx) or silicon oxide (SiOx).

In addition, the first semiconductor layer 140a_1 can include oxide, the second semiconductor layer 140b_1 can include oxide, and the third semiconductor layer 140c can include oxide. That is, the first semiconductor layer 140a_1, the second semiconductor layer 140b_1, and the third semiconductor layer 140c include an oxide material including IGZO or IGTZO, respectively. For example, the first semiconductor layer 140a_1 can include IGZO, ITZO, or IGTZO, the second semiconductor layer 140b_1 can include IGZO, ITZO, or IGTZO, and the third semiconductor layer 140c can include IGZO, ITZO, or IGTZO. For example, the first semiconductor layer 140a_1 may include IGZO, the second semiconductor layer 140b_1 may include IGTZO, and the third semiconductor layer 140c may include IGTZO. Also, a thickness of the second semiconductor layer 140b_1 is higher than a thickness of the first semiconductor layer 140a_1. For example, a thickness of the second semiconductor layer 140b_1 may be greater than a thickness of the first semiconductor layer 140a_1 and a thickness of the third semiconductor layer 140c, and the thickness of the third semiconductor layer 140c may be greater than the thickness of the first semiconductor layer 140a_1. In more detail, the thickness of the first semiconductor layer 140a_1 may be 50 Å, the thickness of the second semiconductor layer 140b_1 may range from 100 Å to 150 Å, and the thickness of the third semiconductor layer 140c may range from 50 Å to 75 Å.

More specifically, a length of the third semiconductor layer 140c can be the same as the length of the first semiconductor layer 140a_1, the third semiconductor layer 140c can overlap the first semiconductor layer 140a_1 in the thickness direction, and the second semiconductor layer 140b_1 can be in contact with each of side surfaces of the first semiconductor layer 140a_1 and the third semiconductor layer 140c. In addition, the second semiconductor layer 140b_1 may not be in contact with an upper surface of the third semiconductor layer 140c due to the first semiconductor layer 140a_1. For example, a length of the second semiconductor layer 140b_1 is same as a length of the first semiconductor layer 140a_1 or a length of the third semiconductor layer 140c. For example, a thin film transistor T_3 can be a driving transistor, or a switching transistor.

In addition, the insulating layer 133 is located between the semiconductor layer 140_2 and the gate electrode 150. The insulating layer 133 includes silicon nitride (SiNx) or silicon oxide (SiOx).

According to the fourth embodiment, even when the hydrogen ions of the buffer layer 131 permeate a semiconductor layer 140_3, the hydrogen ions affect the third semiconductor layer 140c, which is the low mobility semiconductor layer, and do not affect the first semiconductor layer 140a_1 formed on the third semiconductor layer 140c. Therefore, it is possible to prevent the phenomenon that the threshold voltage of the thin film transistor T_3 is negative-shifted.

In addition, by designing the length of the first semiconductor layer 140a_1 to be smaller than the length of the gate electrode 150, the preset channel area of the first semiconductor layer 140a_1 with high electron mobility can be designed to be the same as the effective channel area formed by the conducting process. Therefore, in the thin film transistor manufactured through the conducting process, because the channel area cannot be designed to have a small length due to the problem that the length of the effective channel area of the first semiconductor layer 140a is significantly decreased, it is possible to increase the degree of freedom in element design by solving the problem that the element design is very limited.

In addition, by further arranging the second semiconductor layer 140b_1, which is the low mobility semiconductor layer, between the first semiconductor layer 140a_1 and the gate electrode 150, it is possible to prevent the phenomenon that the threshold voltage (Vth) of the thin film transistor T is positive-shifted, thereby preventing the occurrence of deterioration and degradation of characteristics of the thin film transistor T.

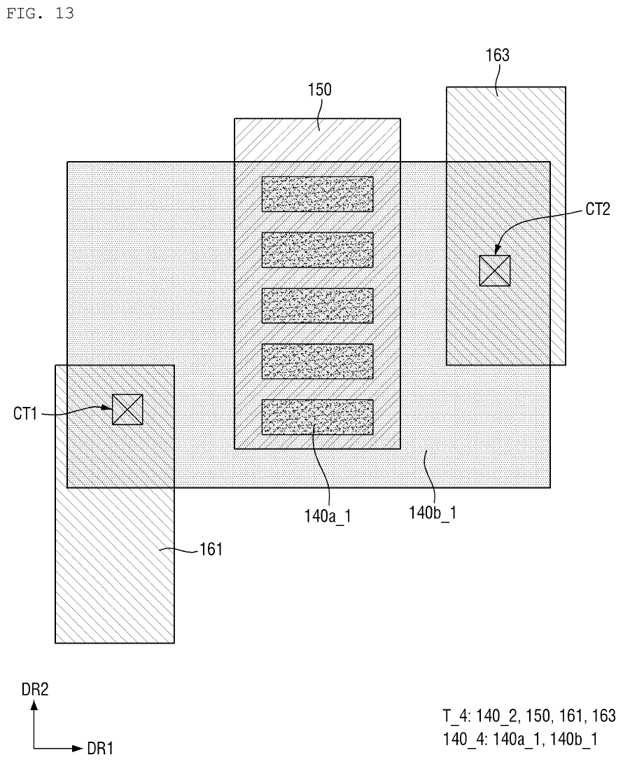

Next, FIG. 13 is a plan view of a thin film transistor according to a fifth embodiment. Referring to FIG. 13, a thin film transistor T_4 according to the fifth embodiment differs from the thin film transistor T_2 according to FIG. 10 in that a width of the semiconductor layer 140_4 is large.

More specifically, a width of the second semiconductor layer 140b_1 of the thin film transistor T_4 can be greater than the second semiconductor layer 140b of FIG. 10. When the width of the semiconductor layer 140_4 increases, the amount of current flowing through the semiconductor layer 140_4 when the thin film transistor T_4 is turned on can increase, and when the amount of current increases, the phenomenon that the thin film transistor is positive-shifted described above in FIGS. 5 and 6 can become more severe.

However, according to the fifth embodiment, the first semiconductor layer 140a_1, which is the high mobility semiconductor layer, can be formed of a plurality of patterns, the plurality of patterns can be designed to be spaced apart from each other in the second direction DR2, and one second semiconductor layer 140b_1 can be designed to cover all of the plurality of patterns. Therefore, by further arranging the second semiconductor layer 140b_1, which is the low mobility semiconductor layer, between the first semiconductor layer 140a_1 and the gate electrode 150 even when the thin film transistor T_4 of which the semiconductor layer 140_4 has a great width, it is possible to prevent the phenomenon that the threshold voltage (Vth) of the thin film transistor T_4 is positive-shifted, thereby preventing the occurrence of deterioration and degradation in characteristics of the thin film transistor T_4.

In the fifth embodiment, a cross-sectional structure of the semiconductor layer 140_4 in a longitudinal direction can be the same as that of FIG. 11. Even in the fifth embodiment, as shown in FIG. 12, the third semiconductor layer, which is the low mobility semiconductor layer, can be further disposed between the first semiconductor layer 140a_1 and the buffer layer 131.

A display device according to embodiments includes a substrate, a semiconductor layer including a first semiconductor layer formed on the substrate and a second semiconductor layer formed on the first semiconductor layer and in contact with side surfaces and an upper surface of the first semiconductor layer, a gate electrode formed on the semiconductor layer and overlapping the first semiconductor layer, and a first electrode formed on the gate electrode and connected to one end of the second semiconductor layer protruding from the first semiconductor layer and a second electrode formed on the gate electrode and connected to the other end of the second semiconductor layer protruding from the first semiconductor layer.

The first semiconductor layer can have greater electron mobility than the second semiconductor layer, a length of the first semiconductor layer can be smaller than a length of the gate electrode, and a length of a channel area of the first semiconductor layer can be the same as a length of an effective channel area of the first semiconductor layer. Further, a length of a channel area of the second semiconductor layer can be larger than a length of an effective channel area of the second semiconductor layer.

In addition, the electron mobility of the first semiconductor layer can be 20 cm2/VS or more, and the electron mobility of the second semiconductor layer can be in the range of 10 cm2/VS to 15 cm2/VS. Further, the semiconductor layer can also include a third semiconductor layer between the first semiconductor layer and the substrate, and a length of the third semiconductor layer can be the same as the length of the first semiconductor layer. The second semiconductor layer can be in contact with side surfaces of the third semiconductor layer.

The display device can further include a lower gate electrode between the substrate and the semiconductor layer, and the same gate voltage can be applied to the gate electrode and the lower gate electrode. The semiconductor layer can also include oxide.

The semiconductor layer, the gate electrode, the first electrode, and the second electrode can form a thin film transistor, and the thin film transistor can be a switching element. The thin film transistor can be a data supply transistor, an emission control transistor or an initialization transistor.

Further, a thin film transistor according to embodiments includes a semiconductor layer including a first semiconductor layer and a second semiconductor layer formed on the first semiconductor layer and fully covering the first semiconductor layer, a gate electrode formed on the semiconductor layer and overlapping the first semiconductor layer, and a first electrode formed on the gate electrode and connected to one end of the second semiconductor layer protruding from the first semiconductor layer and a second electrode formed on the gate electrode and connected to the other end of the second semiconductor layer protruding from the first semiconductor layer.

In addition, a length of the second semiconductor layer can be larger than a length of the first semiconductor layer, and a width of the second semiconductor layer can be greater than a width of the first semiconductor layer. Further, the first semiconductor layer can have greater electron mobility than the second semiconductor layer. Also, a length of the first semiconductor layer can be smaller than a length of the gate electrode, the first semiconductor layer can include a plurality of patterns spaced apart from each other in a width direction, and the second semiconductor layer can cover the plurality of patterns. The semiconductor layer can further include the first semiconductor layer and a third semiconductor layer formed under the first semiconductor layer, and a length of the third semiconductor layer can be the same as the length of the first semiconductor layer.

Although the embodiments of the present invention have been described above with reference to the accompanying drawings, those skilled in the art to which the present invention pertains will be able to understand that the above-described technical configuration of the present invention can be carried out in other specific forms without changing the technical spirit or essential features thereof. Therefore, it should be understood that the above-described embodiments are illustrative and not restrictive in all respects. In addition, the scope of the present invention is described by the claims to be described below rather than the detailed description. In addition, the meaning and scope of the claims and all changed or modified forms derived from the equivalent concept should be construed as being included in the scope of the present invention.

What is claimed is:

1. A display device comprising:
a substrate;
a semiconductor layer including a first semiconductor layer formed on the substrate and a second semiconductor layer formed on the first semiconductor layer, wherein the second semiconductor layer contacts side surfaces and an upper surface of the first semiconductor layer and has a first end protruding away from a first side surface of the first semiconductor layer and a second end protruding away from a second side surface of the first semiconductor layer;
a gate electrode overlapping the first semiconductor layer; and
a first electrode connected to the first end of the second semiconductor layer protruding away from the first side surface of the first semiconductor layer and a second electrode connected to the second end of the second semiconductor layer protruding away from the second side surface of the first semiconductor layer.

2. The display device of claim 1, wherein the first semiconductor layer has a greater electron mobility than the second semiconductor layer.

3. The display device of claim 2, wherein a length of the first semiconductor layer is smaller than a length of the gate electrode.

4. The display device of claim 2, wherein a length of a channel area of the first semiconductor layer is the same as a length of an effective channel area of the first semiconductor layer.

5. The display device of claim 2, wherein a length of a channel area of the second semiconductor layer is larger than a length of an effective channel area of the second semiconductor layer.

6. The display device of claim 2, wherein an electron mobility of the first semiconductor layer is 20 cm2/VS or more, and an electron mobility of the second semiconductor layer is in a range of 10 cm2/VS to 15 cm2/VS.

7. The display device of claim 1, wherein the semiconductor layer includes oxide.

8. The display device of claim 7, wherein the semiconductor layer, the gate electrode, the first electrode, and the second electrode form a thin film transistor, and
the thin film transistor is a switching element.

9. The display device of claim 8, wherein the thin film transistor is a data supply transistor.

10. The display device of claim 8, wherein the thin film transistor may be an emission control transistor or an initialization transistor.

11. A display device comprising:
a flexible substrate;
a semiconductor layer including a first semiconductor layer disposed on the substrate, a second semiconductor layer disposed on the first semiconductor layer and a third semiconductor layer disposed between the first semiconductor layer and the flexible substrate, and
wherein the first semiconductor layer, the second semiconductor layer, and the third semiconductor layer include an oxide material, respectively.

12. The display device according to claim 11, further comprising a thin film transistor comprising:
a gate electrode formed on the semiconductor layer;
a first electrode formed on the gate electrode and connected to the semiconductor layer; and
a second electrode formed on the gate electrode and connected to the semiconductor layer.

13. The display device according to claim 12, further comprising an insulating layer located between the semiconductor layer and the gate electrode, wherein the insulating layer comprises silicon nitride (SiNx) or silicon oxide (SiOx).

14. The display device according to claim 12, wherein the thin film transistor is a switching element or a driving element.

15. The display device according to claim 11, wherein the oxide material includes IGZO or IGTZO.

16. The display device according to claim 15, wherein the first semiconductor layer includes IGZO, the second semiconductor layer includes IGTZO, and third semiconductor layer includes IGTZO.

17. The display device according to claim 11, wherein a thickness of the second semiconductor layer is greater than a thickness of the first semiconductor layer and a thickness of the third semiconductor layer, and the thickness of the third semiconductor layer is greater than the thickness of the first semiconductor layer.

18. The display device according to claim 17, wherein the thickness of the first semiconductor layer is 50 Å, the thickness of the second semiconductor layer ranges from 100 Å to 150 Å, and the thickness of the third semiconductor layer ranges from 50 Å to 75 Å.

19. The display device according to claim 11, wherein the second semiconductor layer is aligned with a side of the first semiconductor layer or a side of the third semiconductor layer.

20. The display device according to claim 11, further comprising a light shielding layer disposed between the substrate and the semiconductor layer and overlapped with the semiconductor layer.

21. The display device according to claim 20, further comprising a buffer layer located between the light shielding layer and the semiconductor layer.

22. The display device according to claim 21, wherein the buffer layer comprises silicon nitride (SiNx) or silicon oxide (SiOx).

23. The display device of claim 20, wherein a same gate voltage is applied to the gate electrode and the lower gate electrode.

24. A thin film transistor comprising:
a semiconductor layer including a first semiconductor layer and a second semiconductor layer formed on the first semiconductor layer and covers upper and side surfaces of the first semiconductor layer, wherein the second semiconductor layer has a first end protruding away from a first side surface of the first semiconductor layer and a second end protruding away from a second side surface of the first semiconductor layer;
a gate electrode overlapping the first semiconductor layer; and
a first electrode connected to the first end of the second semiconductor layer protruding away from the first side surface of the first semiconductor layer and a second electrode connected to the second end of the second semiconductor layer protruding away from the second side surface of the first semiconductor layer.

25. The thin film transistor of claim 24, wherein a length of the second semiconductor layer is larger than a length of the first semiconductor layer.

26. The thin film transistor of claim 24, wherein a width of the second semiconductor layer is greater than a width of the first semiconductor layer.

27. The thin film transistor of claim 24, wherein the first semiconductor layer has greater electron mobility than the second semiconductor layer.

28. The thin film transistor of claim 27, wherein a length of the first semiconductor layer is smaller than a length of the gate electrode.

29. The thin film transistor of claim 28, wherein the first semiconductor layer includes a plurality of patterns spaced apart from each other in a width direction, and the second semiconductor layer covers the plurality of patterns.
